(19) United States
(12) Patent Application Publication
(10) Pub. No.: US 2026/0058687 A1
(43) Pub. Date: Feb. 26, 2026

(54) PREAMPLIFIER CIRCUIT WITH COUPLING FOR WIRED BIDIRECTIONAL COMMUNICATION WITH POWER

(71) Applicant: Interdisciplinary Consulting Corporation, Gainesville, FL (US)

(72) Inventors: William C. Patterson, Gainesville, FL (US); Alan G. Gurlaskie, Gainesville, FL (US); David Alan Mills, Gainesville, FL (US)

(21) Appl. No.: 18/815,148

(22) Filed: Aug. 26, 2024

(51) Int. Cl. H04B 1/44; H03F 3/181; H04B 1/04; H04B 1/3822

(52) U.S. Cl. CPC H04B 1/44; H03F 3/181; H04B 1/0458; H04B 1/3822; H03F 2200/03

(57) ABSTRACT

A preamplifier circuit with coupling for wired bidirectional communication with power is provided. The preamplifier circuit includes a cable connector interface including coupling for two lines; a resistor network coupled to the cable connector interface via the two lines; a transceiver coupled to the resistor network for simultaneous bidirectional communication; a plurality of capacitors arranged between the resistor network and the transceiver; and a power bus coupled to the cable connector interface via the two lines for generating a DC power signal for the preamplifier circuit including the transceiver. A clock signal can be received from a hub front-end simultaneously with outputting a data signal to the hub front-end based on a sensor input. A cable connected between the hub front-end and the preamplifier circuit can be a shielded, two wire cable.

### GOVERNMENT SUPPORT

This invention was made with Government support under contract number 80NSSC22CA057 awarded by NASA. The Government has certain rights in this invention.

### BACKGROUND

The inclusion of sensors and electronics in a variety of systems and environments has been of interest for a variety of applications benefiting from environmental and system operation feedback. When deploying sensors (and related electronics) in different environments and systems, the power consumption, signal strength, communications, and control operations are designed or selected for suitability in those environments and systems.

### BRIEF SUMMARY

A preamplifier circuit with coupling for wired bidirectional communication with power is provided. The described preamplifier circuit is suitable for a wired sensor network that enables connection to a sensor using a single shielded cable consisting of a differential pair and a shared ground (e.g., twisted pair, twinax) such that a power signal and a clock signal can be sent to the sensor and a data signal from the sensor can be sent to another part of the wired sensor network.

A preamplifier circuit as described herein includes a cable connector interface including coupling for two lines; a resistor network coupled to the cable connector interface via the two lines; a transceiver coupled to the resistor network for simultaneous bidirectional communication; a plurality of capacitors arranged between the resistor network and the transceiver; and a power bus coupled to the cable connector interface via the two lines for generating a dc power signal for the preamplifier circuit including the transceiver. A clock signal can be received from a hub front-end simultaneously with outputting a data signal to the hub front-end based on a sensor input.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1A illustrates a preamplifier circuit with coupling for wired bidirectional communication with power.

FIG. 1B illustrates an example implementation of the preamplifier circuit of FIG. 1A.

FIG. 2 illustrates a system having bidirectional communication with power including a preamplifier circuit and a hub front-end.

FIG. 3 illustrates an example of a resistor network that may be used as part of a preamplifier circuit.

FIG. 4 illustrates an example sensor preamplifier that may be used as part of a preamplifier circuit.

FIG. 5 illustrates a hub connected to a plurality of sensors and corresponding preamplifier circuits via corresponding cables.

FIG. 6 illustrates an example scenario in which the described preamplifier circuit and systems can be used.

### DETAILED DESCRIPTION

A preamplifier circuit with coupling for wired bidirectional communication with power is provided. The described preamplifier circuit is suitable for a wired sensor network that enables connection to a sensor using a single shielded cable consisting of a differential pair and a shared ground (e.g., twisted pair, twinax) such that a power signal and a clock signal can be sent to the sensor and a data signal from the sensor can be sent to another part of the wired sensor network.

Advantageously, a single, shielded two-wire standard cable—such as in the form of a twin-axial or shielded twisted pair—can be used to create a wired sensor network with synchronized data collection from multiple sensors in the wired sensor network and a power supply from a central hub. Indeed, simultaneous bidirectional communication along with a power signal is possible over a single, shielded two-wire standard cable.

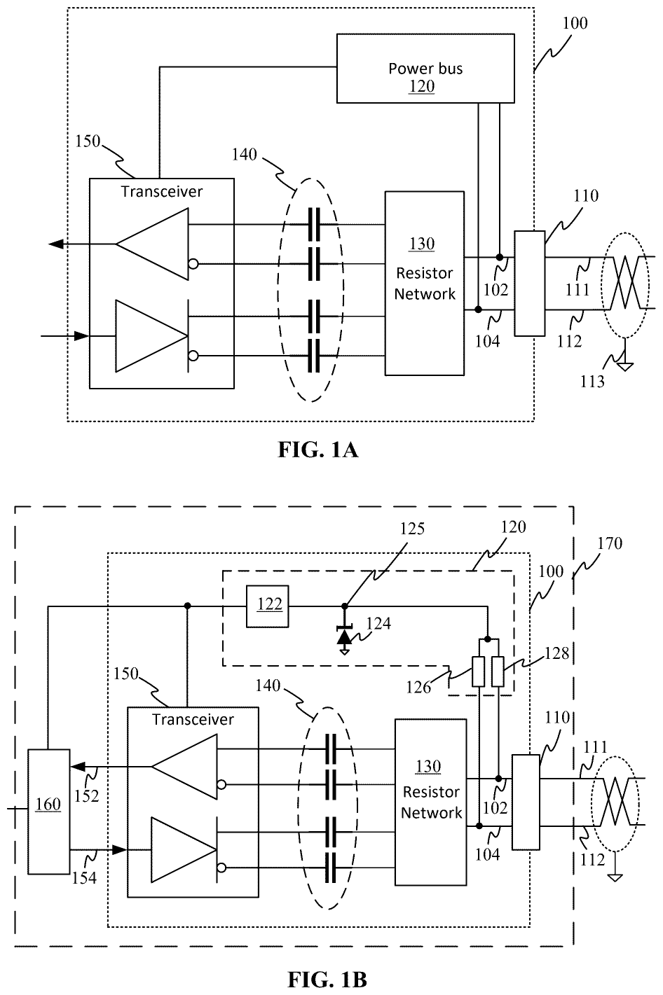

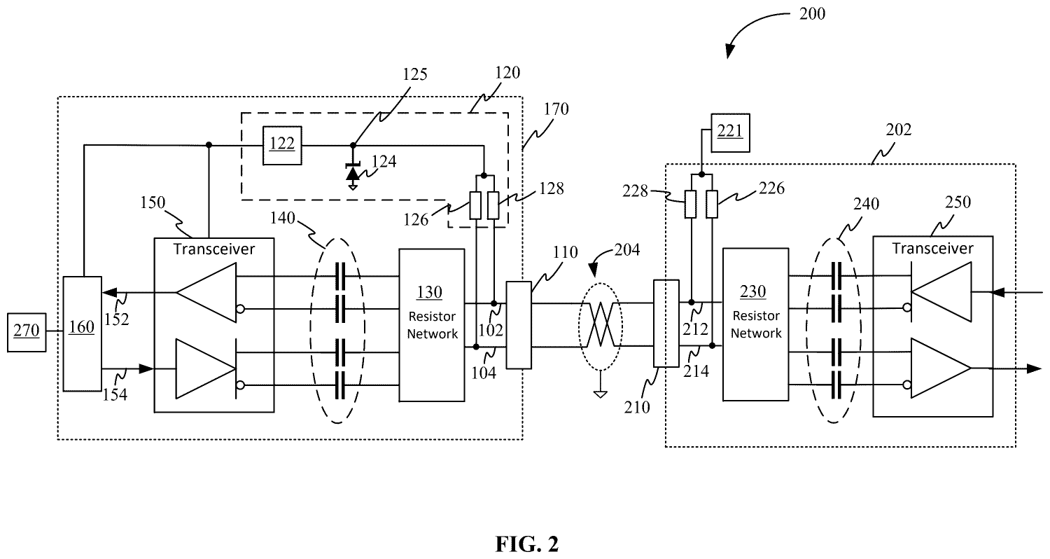

FIG. 1A illustrates a preamplifier circuit with coupling for wired bidirectional communication with power; and FIG. 1B illustrates an example implementation of the preamplifier circuit of FIG. 1A.

Referring to FIG. 1A, a preamplifier circuit 100 with coupling for wired bidirectional communication with power includes a cable connector interface 110, a power bus 120, a resistor network 130, a plurality of capacitors 140, and a transceiver 150. The cable connector interface 110 has coupling for two lines 102, 104. The cable connector interface 110 is configured to couple to a standard shielded two-wire cable, for example, a single twin-axial cable or a shielded twisted pair cable. The cable connector interface 110 is used to provide a wire connection with three conductive parts: two lines in (e.g., first line 111, second line 112) and a ground (113).

The power bus 120 is coupled to the cable connector interface 110 via the two lines 102, 104, and generates, from signals over the lines, a dc power signal for the preamplifier circuit 100 including for the transceiver 150.

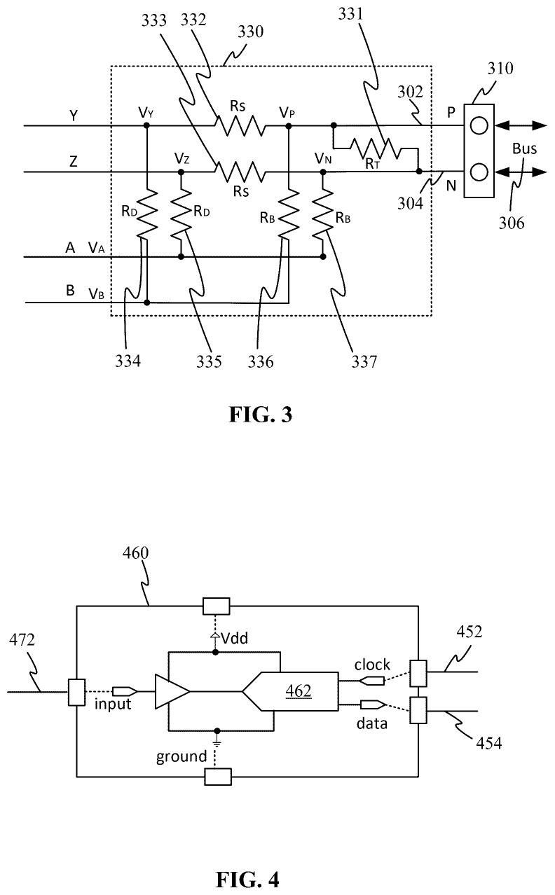

The resistor network 130 is coupled to the cable connector interface 110 via the two lines 102, 104. An example implementation of resistor network 130 is shown in FIG. 3.

The transceiver 150 can be a differential transceiver. The transceiver 150 is coupled to the resistor network for simultaneous bidirectional communication. However, instead of the transceiver 150 receiving an input signal from a connected cable directly from the resistor network 130 and the resistor network 130 receiving an output signal directly from the transceiver 150, the plurality of capacitors 140 are arranged between the resistor network 130 and the transceiver 150.

The plurality of capacitors 140 provide AC coupling so that transmission of DC signals between resistor network 130 and transceiver 150 is inhibited while AC signals between resistor network 130 and transceiver 150 are allowed. In this manner, it is possible to maintain the DC bias point required for operation of the transceiver 150 despite power being provided over the signal lines 102, 104. The described preamplifier circuit 100 is suitable for input/output signals of sufficient frequencies that can pass through the plurality of capacitors. In an example implementation in which the switching frequency of the input and output signals are at least 20 Hz, the capacitors of the plurality of capacitors 140 may be 1 μF to 2.2 μF capacitance capacitors.

Advantageously, the preamplifier circuit 100 powers its components from signals received at the cable connector interface while also supporting simultaneous bidirectional communication.

For example, referring to FIG. 1B, preamplifier circuit 170 can include the components of preamplifier circuit 100 and further include a sensor preamplifier 160 that captures a signal from an analog sensor (not shown), for example, under control of a clock signal 152 that can be received as an input signal over the lines in to the preamplifier circuit 170 (e.g., lines 111, 112 of a cable), and outputs a digital output 154 that can be sent from the preamplifier circuit 170 as an output signal over the lines out of the preamplifier circuit 170 (e.g., using transceiver 150 and resistor network 130). One example of sensor preamplifier 160 is shown in FIG. 4.

In addition, as shown in the example of FIG. 1B, the power bus 120 can include a voltage regulator 122, a diode 124, and resistors 126, 128. Resistors 126, 128 are coupled on one end to lines 102, 104, respectively, and on another end to a node 125 at an input of the voltage regulator 122. Diode 124 is coupled between node 125 and a ground. Resistors 126, 128 respectively couple to lines 102, 104 so voltage regulator 122 (and diode 124) can generate a DC power signal from received signals. That is, the resistors couple the shared differential bus (of lines 102, 104 coupled to the lines 111, 112 of an attached cable via the cable connector interface 110) to the voltage regulator 122 so that power can be provided as needed. Power bus 120 can thus be used to power transceiver 150, sensor preamplifier 160, and any other components coupled to or part of preamplifier circuit 100, 170 (e.g., sensor 270 of FIG. 2) as needed. In some implementations, voltage regulator 122 is or includes a low pass filter. A shared ground can be implemented for the preamplifier circuit 100, 170.

Preamplifier circuit 100, 170 can be used advantageously in a wired sensor network when the preamplifier circuit 100, 170 is connected to a sensor that requires an input signal while also transmitting an output signal at the same time. Sensors receiving an external clock signal, for example, from a main computer or central network, would benefit from the simultaneous, bidirectional communication provided by preamplifier circuit 100, 170 because the sensors can be synchronized with other components in the system or network while still outputting their measured or detected data. Thus, any sensor that relies on an external clock signal, as opposed to an internal clock signal, would benefit from the simultaneous bidirectional communication of preamplifier circuit 100, 170. In various implementations of the present disclosure, sensors connected to preamplifier circuit 100 are detecting or measuring properties of the external environment and are outputting a data signal reflective thereof. The detected or measured properties may vary, fluctuate, stop and start, and/or be irregular, erratic or intermittent.

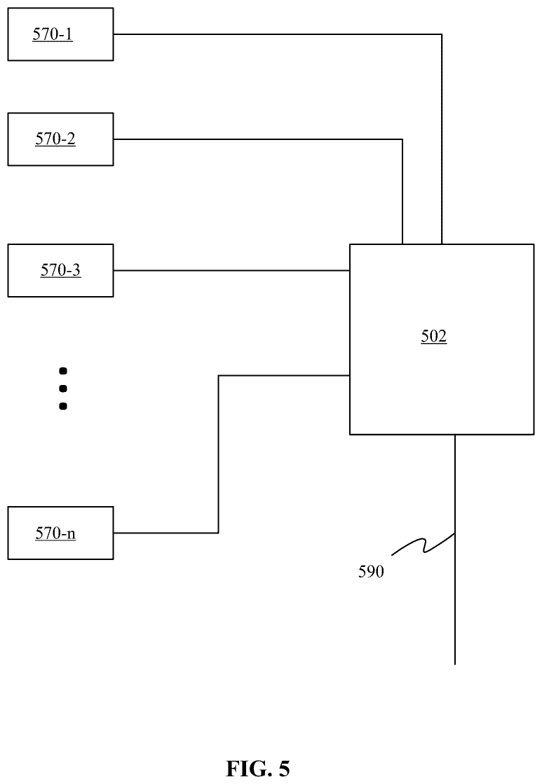

FIG. 2 illustrates a system having bidirectional communication with power including a preamplifier circuit and a hub front-end. Referring to FIG. 2, system 200 includes a hub front-end 202 of a hub to which a preamplifier circuit can be wired. Multiple sensors (and corresponding preamplifier circuits) can be connected through corresponding hub front-ends of the hub which provides power and a clock signal to all the connected sensors (see e.g., FIG. 5). As shown in FIG. 2, preamplifier circuit 170 for sensor 270 is shown connected to the hub front-end 202 by a standard shielded two-wire cable 204.

Here, sensor 270 is coupled to sensor preamplifier 160. Sensor preamplifier 160 receives an analog data output signal from sensor 270 and converts the analog data signal to a digital signal.

In various implementations, sensor 270 is or includes a microphone, for example, a microelectromechanical systems (MEMS) microphone. In various implementations, sensor 270 outputs an electret condenser microphone (ECM) signal to sensor preamplifier 160 which converts the ECM output signal to a digital pulse-density modulation (PDM) data signal. In some of such implementations, sensor preamplifier 160 is or includes a microphone preamplifier with a digital output such as, for example, a FAN3852. FIG. 4 shows an example configuration of a microphone preamplifier.

It should be understood that the present disclosure is not limited to sensors with analog output data streams or to preamplifiers outputting digital PDM data signals. In various implementations, sensors may output analog or digital signals. In various implementations, preamplifiers are optional and in other implementations preamplifiers may output any type of digital signal.

In some cases, sensor 270 can receive power from power bus 120 of the preamplifier circuit 170. The clock signal can be used to synchronize data capture from sensor 270 with other components in system 200.

Aspects of the circuitry of hub front-end 202 mirror aspects of preamplifier circuit 100 described with respect to FIGS. 1A and 1B so as to support the bidirectional communication with power over a shielded two-wire cable 204. For example, hub front-end 202 includes a port or cable connector interface 210 configured to connect to a shielded two-wire cable 204, two lines 212, 214 coupled to the cable connector interface 210 for input and output (and power) of the hub front-end 202, a resistor network 230, a plurality of capacitors 240, and a transceiver 250. Hub front-end 202 can also include a voltage source/power supply 221.

Voltage source 221 is coupled to lines 212, 214 via resistors 226, 228 so as to provide power (e.g., DC voltage) to connected preamplifier circuits over the shielded two-wire cable 204. In some cases, voltage source 221 is also used to supply power to components (e.g., transceiver 250) at the hub front-end 202. Voltage source 221 may be an outlet, battery, or generator, depending on implementation. In some cases, voltage source 221 is a hardware device that converts AC to DC and/or adjusts voltage. In some cases, voltage source 221 is a power connection to another source. Power is transmitted from the hub to the preamplifier circuit as a common-mode DC voltage. The value of the two resistors determines the maximum supply current provided to the preamplifier circuit.

The resistor network 230 is coupled to the cable connector interface 210 via the two lines 212, 214 for bidirectional communication across the cable 204, for example, to receive an input signal and to send an output signal.

The transceiver 250 is configured to receive the input signal from the resistor network 230 and send the output signal to the resistor network 230. However, as explained with respect to the preamplifier circuits of FIGS. 1A and 1B, instead of the transceiver 250 receiving the input signal directly from the resistor network 230 and the resistor network 230 receiving the output signal directly from the transceiver 250, the plurality of capacitors 240 are arranged between the resistor network 230 and the transceiver 250.

The plurality of capacitors 240 provide AC coupling so that transmission of DC signals between resistor network 230 and transceiver 250 is inhibited while AC signals between resistor network 230 and transceiver 250 are allowed. Therefore, it is possible to supply power (e.g., DC voltage) from voltage source 221 to connected preamplifier circuits (e.g., preamplifier circuit 170) over cable 204.

During operation, a power signal from voltage source 221 is sent from hub front-end 202 via resistors 226, 228 and lines 212, 214, respectively, through cable 204 to preamplifier circuit 170. The power signal from hub front-end 202 is captured by power bus 120 to generate a DC power signal from the voltage on the lines 102, 104 resulting from the power signal sent from the hub front-end 202 over cable 204.

At the same time, an input signal, for example, a digital clock input signal, is transmitted from hub front-end 202 via transceiver 250, plurality of capacitors 240, resistor network 230, lines 212, 214, cable connector interface 210, and cable 204 to sensor preamplifier 160 of sensor 270 via cable connector interface 110, resistor network 130, plurality of capacitors 140, and transceiver 150 of the preamplifier circuit 170. The clock signal is used to synchronize data collected from sensor 270 with data collected from additional sensors that are wired from a hub across a larger, distributed system. See FIG. 5.

Also at the same time, an output data signal, for example, based on readings from sensor 270 (e.g., as captured by sensor preamplifier 160), is transmitted from preamplifier circuit 170 via transceiver 150, plurality of capacitors 140, resistor network 130, lines 102, 104, cable connector interface 110, and cable 204 to hub front-end 202 (and the hub via cable connector interface 210, lines 212, 214, resistor network 230, plurality of capacitors 240, and transceiver 250).

In this manner, it is possible to simultaneously provide power and send a clock signal to the preamplifier circuit 170 from the hub front-end 202 via cable 204 and receive a data signal from the preamplifier circuit 170 at the hub front-end 202 via cable 204. As described in more detail with respect to FIG. 3, a 4-to-2 wire conversion between the transceiver 150/250 and resistor network 130/230 is used to distinguish the input signals being received by preamplifier circuit 170 from the output signals being transmitted by preamplifier circuit 170 to provide full-duplex communication over a single cable 204.

FIG. 3 illustrates an example of a resistor network that may be used as part of a preamplifier circuit. The resistor network 330 is configured as described by RENESAS for full-duplex transceivers transmitting full-duplex data over a single twisted pair cable. Resistor network 330 can be used to implement resistor network 130 and resistor network 230 of FIGS. 1A, 1B, and 2. The capacitors between the resistor network and the transceiver are located on lines A, B, Y, and Z. In some cases, the transceiver used in conjunction with resistor network 330 is an RS-485 transceiver. Of course, any differential transmitter and receiver standard may be used for the transceiver.

As illustrated in FIG. 3, resistor network 330 includes seven resistors: a termination resistor R_{T} 331 across the two lines 302, 304 from the cable connector interface 310, a first line resistor R_{S} 332, a second line resistor R_{S} 333, a first driver output resistor R_{D} 334, a second driver output resistor R_{D} 335, a first bus resistor R_{B} 336, and a second bus resistor R_{B} 337. Termination resistor 331 is used to prevent signal reflections on lines 302, 304 (to match the bus node impedance with the characteristic impedance of the bus 306). Linc resistors 332, 333 support termination to the other side of the bus by providing a way to “subtract” the bus voltage from the transceiver output and may reduce current on lines 302, 304 so as to inhibit the drivers of the transceiver from overloading due to both the transmitting driver and the receiving driver being consistently active. The driver output resistors 334, 335 and the bus resistors 336, 337 form resistive voltage dividers with the receiver input impedance (R_{IN}), enabling the input signals on lines 302, 304 to be extracted from the full-duplex (bidirectional) data on the bus 306.

The resistor values selected for the various resistors of resistor network 330 can be determined using the following calculations and relations.

First, because both drivers (i.e., receiving driver and transmitting driver) of the transceiver are active, their output impedance (R_{O}=V₀/I₀) and differential electromotive force (V₀) affect the calculation of all resistor values as well as the voltage relations on the bus. These parameters (R_{O} and V₀) can be determined by drawing a straight, best-fit line through the V-I characteristic of the drivers used in the particular transceiver that is provided in the circuit.

The value R_{S} of the first line resistor 332 and the second line resistor 333 can be calculated so that the impedance looking into the preamplifier bus 306 is the parallel combination of resistors where one resistor is the transmitter output impedance. For example, given an estimate of the transmitter differential output impedance as about 38Ω, R_{S} may be a 68Ω resistor.

Termination resistor 331 is used to match the input impedance of a bus node to the characteristic cable impedance Z₀ (e.g., for Cat 5 cable, Z₀ is 100Ω). In this case, it means the combined impedance of the driver output impedance (R_{O}) and the termination resistor 331 (RT) in parallel to the series circuit of the two line resistors 332, 333 and the series circuit of the phantom power resistors 128, 126 shown in FIGS. 1B and 2 (R_{P}) should equal Z₀. Thus, the value R_{T} of the termination resistor 331 can be given as follows.

$${R}_{T} = \frac{2 {R}_{P} ( {R}_{O} + 2 {R}_{S} ) {Z}_{0}}{2 {R}_{P} ( {R}_{O} + 2 {R}_{S} ) - 2 {R}_{P} {Z}_{O} - ( {R}_{O} + 2 {R}_{S} ) {Z}_{0}} .$$

The value R_{B} of the bus resistors 336, 337 can be selected as 0.1·R_{IN}≥R_{B}≥1 kΩ, where R_{IN} is the receiver input impedance (and based on the particular transceiver used). The value R_{D} of the driver output resistors 334, 335 can then be calculated as follows, where R_{cable} is the resistance of the cable (which can depend on the length of the cable among other contributing factors).

$${R}_{D} = {R}_{B} ( 1 + \frac{2 {R}_{S}}{2 {R}_{P} ‖ {R}_{T} ‖ ( {R}_{c a b l e} + {Z}_{0} )} ) .$$

FIG. 4 illustrates an example sensor preamplifier that may be used as part of a preamplifier circuit. The sensor preamplifier 460 is an example of sensor preamplifier 160 of FIG. 1B that is suitable for a microphone-based sensor. Inputs to sensor preamplifier 460 can include a clock, ground, input, data, and a DC bias voltage (VDD). Sensor preamplifier 460 receives sensor input 472 from the sensor (e.g., sensor 270 of FIG. 2) and a clock input 452 from a transceiver (e.g., transceiver 150 of FIG. 1B). Sensor preamplifier 460 includes a preamplifier and a clocked analog-to-digital converter 462 to generate a digital signal based on sensor input 472. Sensor preamplifier 460 can output the digital signal 454 as data to the transceiver (e.g., transceiver 150). Power may be supplied by power bus 120. Analog-to-digital converter 462 can be a sigma-delta analog-to-digital converter. As an illustrative example, sensor preamplifier 460 converts an electret condenser microphone (ECM) signal to a digital signal, for example, a PDM data signal.

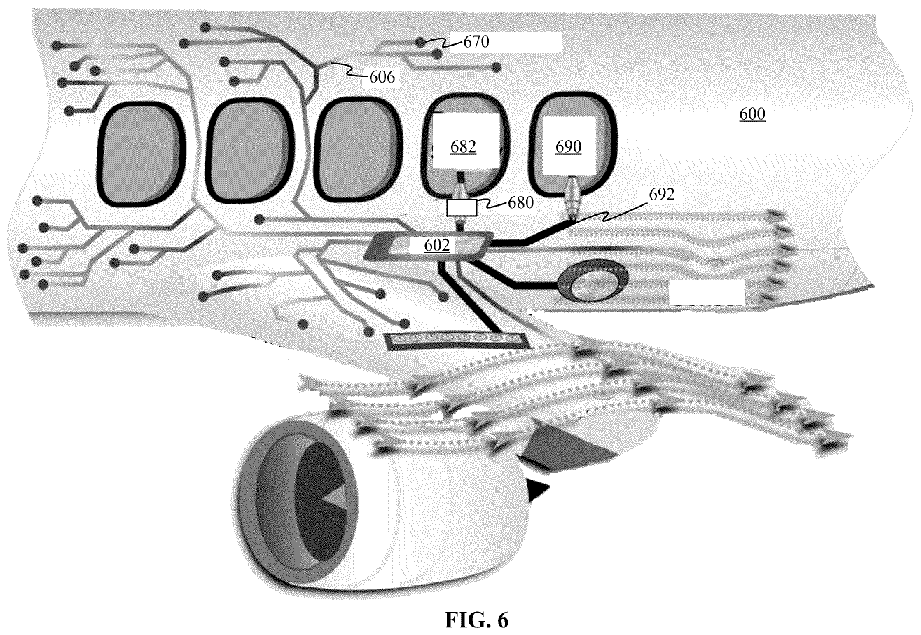

FIG. 5 illustrates a hub connected to a plurality of sensors via corresponding preamplifier circuits and corresponding cables. As explained above, it is possible to provide bidirectional communication with power through incorporating the described preamplifier circuit (and corresponding hub front-end). The bidirectional communication enables synchronization of multiple sensors (each with a preamplifier circuit as described herein) by a hub 502. Hub 502 can include a plurality of hub front-ends (e.g., each hub front-end as described with respect to FIG. 2) for communication with preamplifier circuits of a plurality of sensors 570-1, 570-2, 570-3, . . . 570-n. As illustrated in FIG. 5, hub 502 can be wired to the plurality of sensors 570-1, 570-2, 570-3, . . . 570-n with corresponding cables. The hub 502 can generate the clock signals and provide the power to each of the sensors. Hub 502 can collect the data from the sensors and perform some local processing and/or transmit the data in some form to another system for processing (e.g., via line 590). An example scenario in which hub 502 and sensors may be deployed is shown in FIG. 6.

FIG. 6 illustrates an example scenario in which the described preamplifier circuit and systems can be used. Referring to FIG. 6, an example scenario 600 includes an aircraft fuselage having a plurality of sensors connected to a hub via corresponding preamplifier circuits and corresponding cables. The aircraft fuselage has a plurality of sensors 670 arranged thereon. Each sensor 670 includes a preamplifier circuit such as described herein for simultaneous, bidirectional communication with power and is connected to a corresponding hub front-end of central hub 602 via a dedicated cable 606. Hub 602 is connected by cable to a computer 690 and, optionally to a power supply 682 located within the aircraft. Hub 602 provides a power signal and a reference clock signal to each sensor 670 over shielded cables that do not require a lightning arrester. Hub 602 receives inputs from sensors 670 and converts the data streams from the plurality of sensors 670 into a single optical signal transmitted to computer 690 via fiber connection cable 692 (which may include a lightning arrester). Hub 602 can receive power from the power supply 682 located within the aircraft via a corresponding cable with lightening arrestor 680. In accordance with an advantage of the present disclosure, connection and power supplied to sensors 670 can be made by a standard shielded two-wire cable. As a result, the number of lightening arrestors can be reduced.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

What is claimed is:

1. A preamplifier circuit comprising:
a cable connector interface comprising coupling for two lines;
a resistor network coupled to the cable connector interface via the two lines;
a transceiver coupled to the resistor network for simultaneous bidirectional communication;
a plurality of capacitors arranged between the resistor network and the transceiver; and
a power bus coupled to the cable connector interface via the two lines for generating a DC power signal for the preamplifier circuit including the transceiver.

2. The preamplifier circuit of claim 1, wherein the plurality of capacitors comprises four capacitors, each capacitor on a corresponding line between the resistor network and the transceiver.

3. The preamplifier circuit of claim 1, wherein the power bus comprises:
a voltage regulator;
a first resistor coupled at a first end to one of the two lines and coupled at a second end to a node at an input of the voltage regulator;
a second resistor coupled to another one of the two lines at a corresponding first end and coupled at a corresponding second end to the node; and
a diode coupled to the node.

4. The preamplifier circuit of claim 3, wherein the voltage regulator comprises a low pass filter.

5. The preamplifier circuit of claim 1, further comprising:
a sensor preamplifier having a sensor input, a data input, and a signal output, wherein the sensor preamplifier is coupled to the transceiver to receive a clock signal and output a data signal based on a sensor signal received at the sensor input.

6. The preamplifier circuit of claim 5, wherein the sensor preamplifier is further coupled to the power bus to receive the DC power signal.

7. The preamplifier circuit of claim 1, wherein the cable connector interface is for a single twin-axial cable or a shielded twisted pair cable.

8. The preamplifier circuit of claim 1, wherein an output signal of the transceiver has a frequency sufficient to pass through the plurality of capacitors from the transceiver to the resistor network.

9. The preamplifier circuit of claim 8, wherein the output signal of the transceiver is at least 20 Hz.

10. A bidirectional communication system comprising:
a hub;
the preamplifier circuit of claim 1; and
a single twin-axial cable or a shielded twisted pair cable connecting a hub front-end of the hub to the preamplifier circuit.

11. The bidirectional communication system of claim 10, wherein a power signal at the hub is transmitted from the hub front-end to the preamplifier circuit over the single twin-axial cable or the shielded twisted pair cable.

12. The bidirectional communication system of claim 10, further comprising:
a sensor connected to the preamplifier circuit.

13. The bidirectional communication system of claim 12, wherein the sensor receives the DC power signal generated by the power bus of the preamplifier circuit.

14. The bidirectional communication system of claim 12, wherein the sensor includes a microphone.

15. The bidirectional communication system of claim 10, wherein the preamplifier circuit includes a sensor preamplifier.

16. The bidirectional communication system of claim 10, wherein the hub front-end comprises:
a hub cable connector interface configured to connect to the single twin-axial cable or the shielded twisted pair cable;
a third resistor coupled at a first end to one of two hub lines coupled to the hub cable connector interface and coupled at a second end to a voltage source; and
a fourth resistor coupled to another one of the two hub lines at a corresponding first end and coupled at a corresponding second end to the voltage source.

17. The bidirectional communication system of claim 16, wherein the hub front-end further comprises:
a hub resistor network coupled to the hub cable connector interface via the two hub lines;
a hub transceiver coupled to the hub resistor network for simultaneous bidirectional communication; and
a plurality of hub capacitors arranged between the hub resistor network and the hub transceiver.

18. The bidirectional communication system of claim 17, wherein the hub simultaneously sends a clock signal to the preamplifier circuit and receives a data signal from the preamplifier circuit, and wherein the preamplifier circuit simultaneously receives the clock signal from the hub and sends the data signal to the hub.

19. The bidirectional communication system of claim 17, wherein the preamplifier circuit is provided in plurality, the hub comprising a corresponding plurality of hub front-ends.
